(19) United States
(12) Patent Application Publication
(10) Pub. No.: US 2024/0395992 A1
(43) Pub. Date: Nov. 28, 2024

(54) PACKAGED CHIP AND BACKLIGHT MODULE INCLUDING THE SAME

(71) Applicants: InnoLux Corporation, Miao-Li County (TW); CARUX TECHNOLOGY PTE. LTD., SINGAPORE (SG)

(72) Inventors: Chia-Lun CHEN, Miao-Li County (TW); Li-Wei SUNG, Tainan (Tainan Science Park) (TW); Shih-Chang HUANG, Miao-Li County (TW)

(21) Appl. No.: 18/647,013

(22) Filed: Apr. 26, 2024

(30) Foreign Application Priority Data
May 24, 2023 (CN) 202310591785.3

(51) Int. Cl. H01L 33/62; H01L 25/13; H01L 33/52; H10K 50/844; H10K 50/88; H10K 59/95

(52) U.S. Cl. CPC H01L 33/62; H01L 25/13; H01L 33/52; H10K 50/844; H10K 50/88; H10K 59/95

(57) ABSTRACT

A packaged chip and a backlight module including the same are provided. The packaged chip includes a base material, a chip, and a packaging layer. The base material includes a first electrode. The chip is disposed on the base material and is electrically connected with the first electrode. The packaging layer is disposed on the base material and surrounds the chip. The base material includes a surface. A first distance is between a top surface of the chip and the surface of the base material. The surface of the base material includes a coupling portion. In a cross-sectional direction, a height or a depth of the coupling portion is less than the first distance.

### CROSS REFERENCE TO RELATED APPLICATIONS

This application claims priority of China Patent Application No. CN 202310591785.3, filed on May 24, 2023, the entirety of which is incorporated by reference herein.

### TECHNICAL FIELD

Some embodiments of the present disclosure relate to a packaged chip and a backlight module including the same, and, in particular, to a packaged chip including a coupling portion and a backlight module including the packaged chip.

### BACKGROUND

Electronic products with chips, such as displays, smartphones, tablets, notebook computers, and televisions, have become indispensable necessities in modern society. With the booming development of this type of electronic product, consumers have high expectations for the quality, functionality, or price of these electronic products.

Therefore, a packaging process is usually performed to improve the reliability of chips. For example, the structural strength of a packaged chip after the packaging process can be improved by providing a protective layer. However, providing a protective layer will lead to too many interfaces, which will reduce the luminous efficiency or reduce the light-mixing capabilities of the chip. Therefore, these electronic products do not meet consumer expectations in all respects, and there are still some problems in electronic products. The development of packaged chips that can improve luminous efficiency or light-mixing capabilities and backlight modules including the packaged chips is still one of the current goals.

### SUMMARY

In some embodiments, a packaged chip is provided. The packaged chip includes a base material, a chip, and a packaging layer. The base material includes a first electrode. The chip is disposed on the base material and electrically connected with the first electrode. The packaging layer is disposed on the base material and surrounds the chip. Wherein, the base material includes a surface. A first distance is between a top surface of the chip and the surface of the base material. The surface of the base material includes a coupling portion. In a cross-sectional direction, a height or a depth of the coupling portion is less than the first distance.

In some embodiments, a backlight module is provided. The backlight module includes a substrate and a plurality of packaged chips. The plurality of packaged chips is disposed on the substrate. Wherein, at least one of the plurality of packaged chips includes a base material, a chip, and a packaging layer. The base material includes a first electrode. The chip is disposed on the base material and electrically connected with the first electrode. The packaging layer is disposed on the base material and surrounds the chip. Wherein, the base material includes a surface. A first distance is between a top surface of the chip and the surface of the base material. The surface of the base material includes a coupling portion. In a cross-sectional direction, a height or a depth of the coupling portion is less than the first distance.

The packaged chip or the backlight module of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows a schematic cross-sectional view of a packaged chip according to some embodiments of the present disclosure.

FIG. 2 shows a schematic top view of a packaged chip according to some embodiments of the present disclosure.

FIG. 3 shows a schematic cross-sectional view of a packaged chip according to some embodiments of the present disclosure.

FIG. 4 shows a schematic top view of a packaged chip according to some embodiments of the present disclosure.

FIG. 5 shows a schematic cross-sectional view of a packaged chip according to some embodiments of the present disclosure.

FIG. 6 shows a schematic top view of a packaged chip according to some embodiments of the present disclosure.

FIG. 7 shows a schematic cross-sectional view of a packaged chip according to some embodiments of the present disclosure.

FIG. 8 shows a schematic top view of a packaged chip according to some embodiments of the present disclosure.

FIG. 9 shows a schematic cross-sectional view of a packaged chip according to some embodiments of the present disclosure.

FIG. 10 shows a schematic top view of a packaged chip according to some embodiments of the present disclosure.

FIGS. 11 to 15 respectively show schematic top views of packaged chips according to some embodiments of the present disclosure.

FIG. 16 shows a schematic diagram of a backlight module according to some embodiments of the present disclosure.

FIG. 17 shows a schematic diagram of a backlight module according to some embodiments of the present disclosure.

FIG. 18 shows a schematic diagram of a backlight module according to some embodiments of the present disclosure.

### DETAILED DESCRIPTION

Packaged chips or backlight modules of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar and/or corresponding reference numerals may be used in different embodiments to designate similar and/or corresponding elements in order to clearly describe the present disclosure. However, the use of these similar and/or corresponding reference numerals is only for the purpose of simply and clearly description of some embodiments of the present disclosure, and does not imply any correlation between the different embodiments and/or structures discussed.

It should be understood that relative terms, such as “lower”, “bottom”, “higher” or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second” and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connecting”, “interconnecting”, “bonding”, and the like, unless otherwise defined, may refer to two structures in direct contact, or may also refer to two structures not in direct contact, that is there is another structure disposed between the two structures. Moreover, the terms related to connection and bonding can also include embodiments in which both structures are movable, or in which both structures are fixed. Furthermore, the terms “electrically connected” or “electrically coupled” include any direct and indirect means of electrical connection.

Herein, the terms “about”, “approximately”, and “substantially” generally mean within 10%, within 5%, within 3%, within 2%, within 1%, or within 0.5% of a given value or range. The given value is an approximate value, that is, “about”, “approximately”, and “substantially” can still be implied without the specific description of “about”, “approximately”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 1% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in this disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (height direction or thickness direction). In some embodiments, the schematic cross-sectional views described herein are schematic views observing the XZ plane. That is, the cross-sectional direction is a direction observing the XZ plane. In some embodiments, the schematic top views described herein are schematic views observing the XY plane. That is, the top view direction is a direction observing the XY plane.

It should be understood that, according to the embodiments of the present disclosure, the depth, the thickness, the width, or the height of each element, as well as the space or distance between elements, may be measured using an optical microscope (OM), a scanning electron microscope (SEM), a film thickness profiler (α-step), an ellipsometer, or another suitable method. In detail, according to some embodiments, a cross-sectional structure image including an element to be measured may be obtained by using the scanning electron microscope, and then the depth, the thickness, the width, or the height of each element, and the spacing or the distance between elements, may be measured.

In some embodiments, the electronic device of the present disclosure may include a display module, a back light module, an antenna module, a sensing module, or a titling module, but the present disclosure is not limited thereto. The electronic device may be a foldable or flexible electronic device. The display module may be a non-self-luminous display module or a self-luminous display module. The antenna module may be a liquid crystal antenna module or a non-liquid crystal antenna module. The sensing module may be a sensing module for sensing capacitance, light, heat, or ultrasonic waves, but the present disclosure is not limited thereto. The electronic unit may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling module may be, for example, a display titling module or an antenna titling module, but the present disclosure is not limited thereto. It should be noted that, the electronic device can be any arrangement and combination of the foregoing, but the present disclosure is not limited thereto. Hereinafter, a packaged chip and a backlight module including the packaged chip are used to illustrate the content of the present disclosure, but the present disclosure is not limited thereto.

In addition, the shape of the electronic device may be rectangular, circular, polygonal, a shape with curved edges, or another suitable shape. The electronic device may have a peripheral system, such as a processing system, a driving system, a control system, a light source system, a shelf system, or the like to support the display module or titling module.

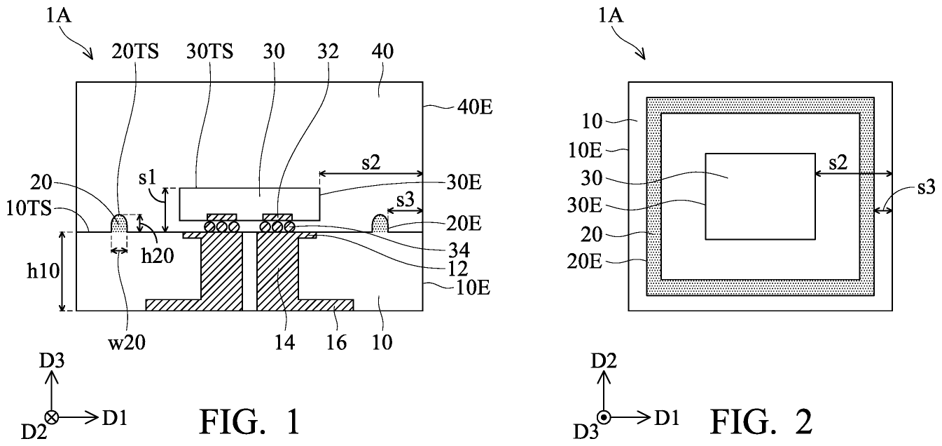

Referring to FIGS. 1 and 2, they respectively show a schematic cross-sectional view and a top view of a packaged chip 1A according to some embodiments of the present disclosure. It should be understood that, for clarity of explanation, some components of the packaged chip 1A are omitted in the drawings, and some components are schematically illustrated. In some embodiments, additional components may be added to packaged chip 1A as described below. In other embodiments, some components of the packaged chip 1A described below may be replaced or omitted. It should be understood that, in some embodiments, additional steps may be provided before, during, and/or after the method of forming the packaged chip 1A. In some embodiments, some of the steps described below may be replaced or omitted, and the order of some of the steps described below is interchangeable. For convenience of explanation, FIG. 2 shows the base material 10, the coupling portion 20, and the chip 30.

As shown in FIG. 1, in some embodiments, the packaged chip 1A may include a base material 10. In some embodiments, the base material 10 may include epoxy molding compound (EMC), bismaleimide triazine (BT), Ajinomoto build up film (ABF), glass fiber, the like, or a combination thereof, but the present disclosure is not limited thereto.

In some embodiments, base material 10 may have a top surface 10TS. In some embodiments, in the normal direction of the base material 10 (the third direction D3), there is a height h10 between the bottom surface of the base material 10 and the top surface 10TS of the base material 10. In some embodiments, the height h10 of the base material 10 may be greater than or equal to 150 micrometers (um) and less than or equal to 300 micrometers (um). For example, the height h10 of the base material 10 may be 150 μm, 175 um, 200 μm, 225 um, 250 μm, 275 um, 300 μm, or any value or range of values between the abovementioned values, but the present disclosure is not limited thereto.

As shown in FIG. 1, the base material 10 may include a first electrode 12, a conductive structure 14, and a bonding pad 16 to provide a conductive path in the base material 10. The conductive structure 14 is disposed between the first electrode 12 and the bonding pad 16 and is electrically connected to the first electrode 12 and the bonding pad 16. In some embodiments, the conductive structure 14 may include vias, wires, conductive layers, the like, or a combination thereof, but the present disclosure is not limited thereto. In some embodiments, the bonding pad 16 may electrically connect the packaged chip 1A to other external components. The first electrode 12, the conductive structure 14, and/or the bonding pad 16 may include a conductive material. The conductive material may include metal conductive material, transparent conductive material, or a combination thereof. For example, the metal conductive material may include copper (Cu), aluminum (Al), molybdenum (Mo), silver (Ag), tin (Sn), tungsten (W), gold (Au), chromium (Cr), nickel (Ni), platinum (Pt), other suitable metals or alloys thereof, the like, or a combination thereof, but the present disclosure is not limited thereto. For example, the transparent conductive material may include transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the first electrode 12, the conductive structure 14, and/or the bonding pad 16 may be formed by a deposition process, a sputtering process, an etching process, the like, or a combination thereof.

As shown in FIG. 1, the packaged chip 1A may further include a chip 30. In some embodiments, the chip 30 is disposed on the base material 10 and is electrically connected to the first electrode 12 in the base material 10. In some embodiments, the chip 30 may include an organic light-emitting diode (OLED), a mini light-emitting diode (mini LED), a micro light-emitting diode (micro LED), or a quantum dot light emitting diode. (quantum dot LED), but the present disclosure is not limited thereto. In some embodiments, the chip 30 may include a second electrode 32, and the second electrode 32 of the chip 30 at least partially overlaps the first electrode 12 in the base material 10 in the normal direction of the base material 10. The second electrode 32 of the chip 30 is electrically connected to the first electrode 12 in the base material 10. In some embodiments, the packaged chip 1A may further include a bonding element 34 disposed between the second electrode 32 of the chip 30 and the first electrode 12 in the base material 10. The first electrode 12 and the second electrode 32 are bonded by the bonding element 34, and the bonding element 34 electrically connects the first electrode 12 and the second electrode 32. In some embodiments, the bonding element 34 may include the conductive material, for example, the bonding element 34 may be a solder ball, such as a solder ball. In some embodiments, a bonding process may be performed to form the bonding element 34 between the first electrode 12 of the base material 10 and the second electrode 32 of the chip 30, in order to bond the first electrode 12 and the second electrode 32.

The chip 30 has a top surface 30TS away from the base material 10, and the top surface 30TS may be a surface of the chip 30 that is not provided with the second electrode 32. In the normal direction of the base material 10, there is a first distance s1 between the top surface 10TS of the base material 10 and the top surface 30TS of the chip 30. In some embodiments, the first distance s1 may be greater than or equal to 80 μm and less than or equal to 200 μm. For example, the first distance s1 may be 80 μm, 100 um, 125 μm, 150 um, 175 μm, 200 um, or any value or range of values between the abovementioned values, but the present disclosure is not limited thereto. In some embodiments, the type of the chip 30 and/or the size of the bonding element 34 may be adjusted in order to adjust the first distance s1.

As shown in FIG. 1, the packaged chip 1A may further include a packaging layer 40, and the packaging layer 40 may be disposed on the base material 10 and surround the chip 30. In some embodiments, the packaging layer 40 may be disposed on the top surface 10TS of the base material 10, and the packaging layer 40 may be disposed on the bottom surface, side surfaces, and top surface 30TS of the chip 30. Based on the arrangement, the packaged chip may have the advantage of multi-sides light-emitting (for example, four-side light-emitting or five-side light-emitting). In some embodiments, the packaging layer 40 may be further disposed on the side surface of the bonding element 34 and/or between the bottom surface of the chip 30 and the top surface of the base material 10. The packaging layer 40 may include a packaging matrix and dispersed particles dispersed in the packaging matrix. The packaging matrix may include a resin material or the like, but the present disclosure is not limited thereto. For example, the packaging matrix may include silicone resin, epoxy resin, acrylic-based resin, the like, or a combination thereof, but the present disclosure is not limited thereto. The dispersed particles may include light-conversion material. For example, the light-conversion material may include nitride-based phosphors, silicate-based phosphors, fluoride-based phosphors, quantum dots, the like, or a combination thereof, but the present disclosure is not limited thereto. In some embodiments, the packaging layer 40 is in contact with the chip 30, and molding material is omitted between the packaging layer 40 and the chip 30.

As shown in FIG. 1, the top surface 10TS of the base material 10 may include a coupling portion 20 to enhance the structural strength (for example, the interface strength or mechanical strength) between the base material 10 and the packaging layer 40 in connected the base material 10. For example, since the base material 10 and the packaging layer 40 formed on the base material 10 are vertically stacked in the normal direction of the base material 10, the structural strength between the base material 10 and the packaging layer 40 may be insufficient and may be damaged by external forces. For example, it may be damaged by the lateral thrust force along the first direction D1 and/or the second direction D2, and/or it may be damaged by the vertical separation force along the third direction D3. Therefore, the coupling portion 20 on the top surface 10TS of the base material 10 may increase the contact area between the base material 10 and the packaging layer 40, thereby improving the structural strength of the base material 10 and the packaging layer 40 or improving the reliability of packaged chip 1A. Furthermore, since the coupling portion 20 is provided between the top surface 10TS of the base material 10 and the packaging layer 40 in the normal direction of the base material 10, it is possible to omit the provision of a protective layer on the side surface of the packaged chip 1A (for example, along the first direction D1 and/or the second direction D2), thereby avoiding the problem of reducing the light-mixing capability of the chip 30 due to the protective layer. Accordingly, providing the coupling portion 20 may improve the light-mixing capability of the chip 30 or improve the optical characteristics of the packaged chip 1A.

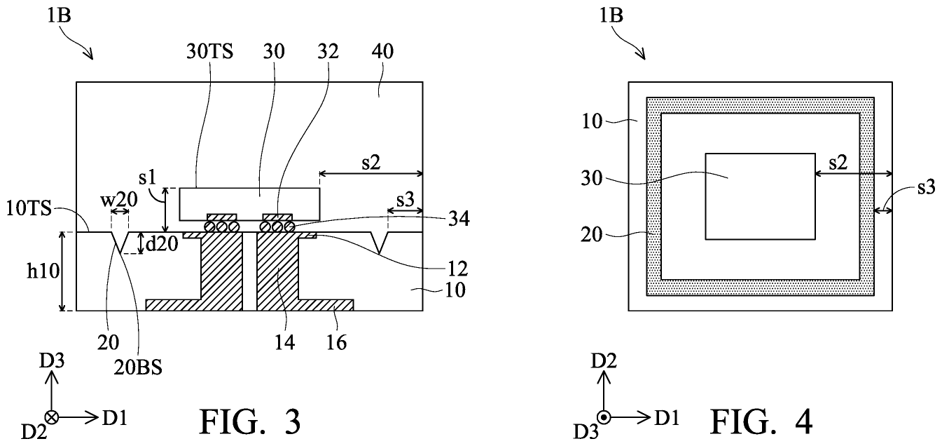

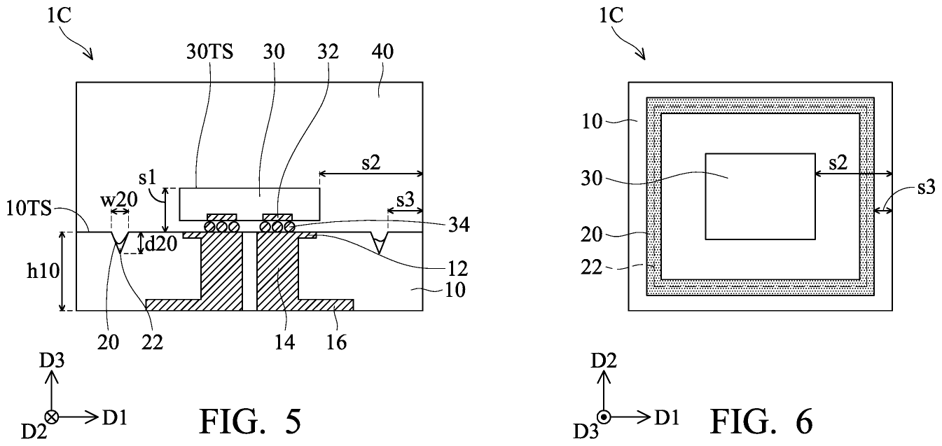

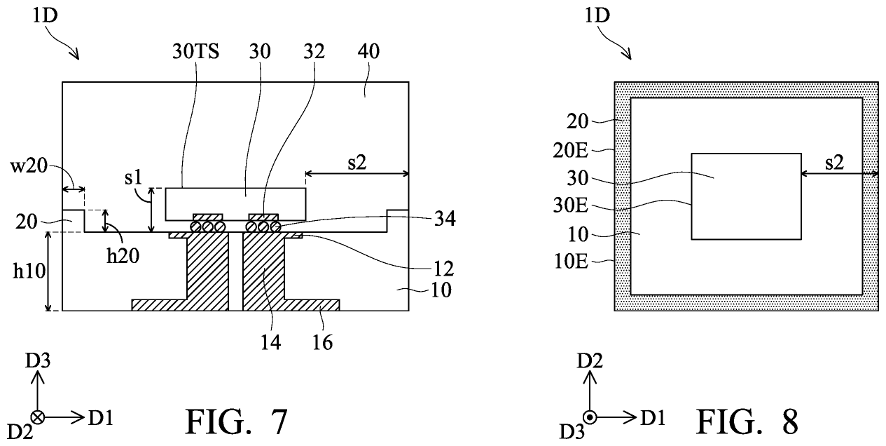

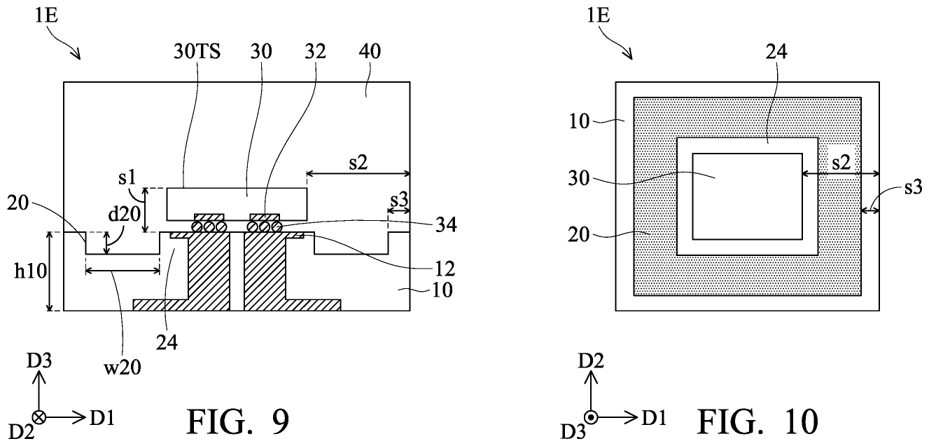

In the cross-sectional direction (the plane formed by the first direction D1 and the third direction D3), the height h20 (as shown in FIG. 1) or the depth d20 (as shown in FIG. 3) of the coupling portion 20 may be smaller than the first distance s1, in order to prevent the coupling portion 20 from blocking the traveling path of light emitted by the chip 30 thereby reducing the luminous efficiency of the chip 30, or damaging the components in the base material 10 (for example, the first electrode 12, the conductive structure 14, or the bonding pad 16) thereby reducing the reliability of the packaged chip 1A. In some embodiments, the coupling portion 20 may include a protrusion (as shown in FIG. 1 or FIG. 7), a recess (as shown in FIG. 3, FIG. 5, or FIG. 9), or a combination thereof, but the present disclosure is not limited thereto.

As shown in FIG. 1, when the coupling portion 20 is a protrusion, the coupling portion 20 may have a rectangular, triangular, semicircular, semielliptical, bullet-shaped, or other suitable shape, but the present disclosure is not limited thereto. In some embodiments, the coupling portion 20 has an arc top profile or a tip top profile, but the present disclosure is not limited thereto.

In some embodiments, the base material 10 and the coupling portion 20 may be formed in the same process or may be formed successively in different processes. In some embodiments, the base material 10 and the coupling portion 20 may be formed by an injection molding process. For example, the base material 10 with the coupling portion 20 may be formed by the injection molding process using mold processing. The coupling portion 20 may increase the surface roughness of the top surface 10TS of the base material 10. In this embodiment, the base material 10 and the coupling portion 20 are made of the same material. In this embodiment, the base material 10 may include an epoxy molding compound (EMC).

In other embodiments, the base material 10 may be formed, and then the coupling portion 20 may be formed on the base material 10. For example, the coupling portion 20 may be formed on the base material 10 by a coating process. In this embodiment, the materials of the base material 10 and the coupling portion 20 may be the same or different. In some embodiments, the reflectivity of the material of the coupling portion 20 may be greater than or equal to 90%. For example, the reflectivity of the material of the coupling portion 20 may be 90%, 93%, 95%, 97%, 99%, or any value or range of values between the abovementioned values, but the present disclosure is not limited thereto. In some embodiments, the coupling portion 20 may include white reflective material. After the base material 10 and the coupling portion 20 are formed, the chip 30 may be formed on the base material 10. Then, the packaging layer 40 is formed on the base material 10 so that the packaging layer 40 is in contact with the coupling portion 20. For example, the material of the packaging layer 40 may fill the coupling portion 20 or the material of the packaging layer 40 may surround the coupling portion 20.

In some embodiments, the height h20 or the depth d20 of the coupling portion 20 may be measured with the top surface 10TS of the base material 10 as a reference point. In some embodiments, if the coupling portion 20 protrudes from the base material 10 along the normal direction of the base material 10, the coupling portion 20 is a protrusion, and the coupling portion 20 has the height h20 from the top surface 10TS of the base material 10 to the top surface 20TS of the coupling portion 20 (as shown in FIG. 1). In other embodiments, if the coupling portion 20 is recessed into the base material 10 along a direction opposite to the normal direction of the base material 10, the coupling portion 20 is a recess, and the coupling portion 20 has the depth d20 from the top surface 10TS of the base material 10 to the bottom surface 20BS of the coupling portion 20 (as shown in FIG. 3).

In some embodiments, the height h20 or the depth d20 of the coupling portion 20 may be greater than 0 and less than or equal to 100 μm. For example, the height h20 or the depth d20 of the coupling portion 20 may be 1 μm, 10 um, 20 μm, 30 um, 40 μm, 50 um, 60 μm, 70 um, 80 μm, 90 um, 100 μm, or any value or range of values between the abovementioned values, but the present disclosure is not limited thereto. In some embodiments, the height h20 or the depth d20 of the coupling portion 20 may be greater than 0 and less than or equal to half of the first distance s1 to prevent the coupling portion 20 from blocking the traveling path of light emitted by the chip 30 or damaging components in base material 10. For example, the ratio of the height h20 or depth d20 of the coupling portion 20 to the first distance s1 (the height h20/the first distance s1, or the depth d20/the first distance s1) is 0.5, 0.4, 0.3, 0.2, 0.1, or any value or range of values between the abovementioned values, but the present disclosure is not limited thereto.

As shown in FIG. 1, the coupling portion 20 may have a width w20 in the first direction D1. In some embodiments, the width w20 of the coupling portion 20 may be greater than or equal to 10 μm and less than or equal to 150 um, but the present disclosure is not limited thereto.

As shown in FIGS. 1 and 2, in some embodiments, in the first direction D1, the edge 40E of the packaging layer 40 is substantially aligned with the edge 10E of the base material 10. In some embodiments, the edge 30E of the chip 30 is spaced apart from the edge 10E of the base material 10 by a second distance s2. In some embodiments, the edge 20E of the coupling portion 20 adjacent the edge 10E of the base material 10 is spaced apart from the edge 10E of the base material 10 by a third distance s3. In some embodiments, the third distance s3 may be greater than or equal to 0 and less than or equal to half of the second distance s2 to prevent the coupling portion 20 from blocking the traveling path of the light emitted by the chip 30. For example, the ratio of the third distance s3 to the second distance s2 (the third distance s3/the second distance s2) is 0.5, 0.4, 0.3, 0.2, 0.1, or any value or range of values between the abovementioned values, but the present disclosure is not limited thereto.

As shown in FIG. 2, in some embodiments, in the top view direction (the plane formed by the first direction D1 and the second direction D2), the coupling portion 20 may surround the chip 30. In some embodiments, the coupling portion 20 may cover (for example, completely cover) the side surfaces of the chip 30 to increase the contact area between the base material 10 and the packaging layer 40. In some embodiments, the area of the packaged chip 1A may be 0.05 square millimeters (mm²), 0.2 mm², 0.5 mm², 1.5 mm², 3 mm², 5 mm², 8 mm², 13 mm², 20 mm², 28 mm², or any value or range of values between the abovementioned values, but the present disclosure is not limited thereto.

Referring to FIGS. 3 and 4, they respectively show a schematic cross-sectional view and a top view of a packaged chip 1B according to some embodiments of the present disclosure. For convenience of explanation, FIG. 4 shows the base material 10, the coupling portion 20, and the chip 30, and the dotted filling pattern shows the arrangement position of the coupling portion 20 as a recess. FIGS. 3 and 4 show embodiments in which the coupling portion 20 is a recess. In the cross-sectional direction, when the coupling portion 20 is a recess, the coupling portion 20 may have a V-shape (as shown in FIGS. 3 and 5), a U-shape, a semicircular shape, a semielliptical shape, or a rectangular shape (as shown in FIG. 9), or other suitable shapes, but the present disclosure is not limited thereto. In some embodiments, the coupling portion 20 has a tip bottom profile or an arc bottom profile, but the present disclosure is not limited thereto. As shown in FIGS. 3 and 4, in some embodiments, the coupling portion 20 may surround the chip 30, and the coupling portion 20 may be spaced a distance from the edge of the chip 30. In some embodiments, the material of packaging layer 40 may fill the coupling portion 20.

Referring to FIGS. 5 and 6, they respectively show a schematic cross-sectional view and a top view of a packaged chip 1C according to some embodiments of the present disclosure. FIGS. 5 and 6 show an embodiment in which the coupling portion 20 is a recess. As shown in FIG. 5, in some embodiments, the material of the packaging layer 40 does not completely fill the coupling portion 20, so that a portion of the packaging layer 40 is physically separated from the base material 10. In some embodiments, the packaged chip 1C may further include an air gap 22 between the coupling portion 20 of the base material 10 and the packaging layer 40. In some embodiments, the air gap 22 may include air, an inert gas such as nitrogen, or the air gap 22 may be a vacuum. In some embodiments, the air gap 22 may be continuously (as shown in dashed lines in FIG. 6) or discontinuously surround the chip 30. As shown in FIGS. 5 and 6, in some embodiments, the coupling portion 20 may surround the chip 30, and the coupling portion 20 may be spaced a distance from the edge of the chip 30.

Referring to FIGS. 7 and 8, they respectively show a schematic cross-sectional view and a top view of a packaged chip 1D according to some embodiments of the present disclosure. FIGS. 7 and 8 show embodiments in which the coupling portion 20 is a protrusion. In some embodiments, as shown in FIG. 8, the coupling portion 20 is disposed on the edge 10E of the base material 10. In some embodiments, in the first direction D1, the edge 20E of the coupling portion 20 is substantially aligned with the edge 10E of the base material 10. In some embodiments, the third distance s3 between the edge 20E of the coupling portion 20 and the edge 10E of the base material 10 is 0. In this embodiment, the coupling portion 20 is positioned far away from the chip 30 to prevent the coupling portion 20 from blocking the traveling path of light emitted by the chip 30. In some embodiments, the top surface of coupling portion 20 may be higher than the bottom surface of chip 30.

Referring to FIGS. 9 and 10, they respectively show a schematic cross-sectional view and a top view of a packaged chip 1E according to some embodiments of the present disclosure. In some embodiments, the base material 10 further includes an island portion 24. In the cross-sectional direction, the coupling portion 20 may surround the island portion 24, and the chip 30 and the bonding element 34 may be disposed on the island portion 24. In some embodiments, since the chip 30 is disposed on the island portion 24, the top surface of the base material 10 may be lower than the bottom surface of the chip 30 to prevent the coupling portion 20 from blocking the traveling path of light emitted by the chip 30. In some embodiments, in the first direction D1, the coupling portion 20 and the island portion 24 may be disposed adjacent to each other. In this embodiment, as shown in FIG. 10, the ratio of the third distance s3 to the second distance s2 may be less than or equal to 0.3, but the present disclosure is not limited thereto.

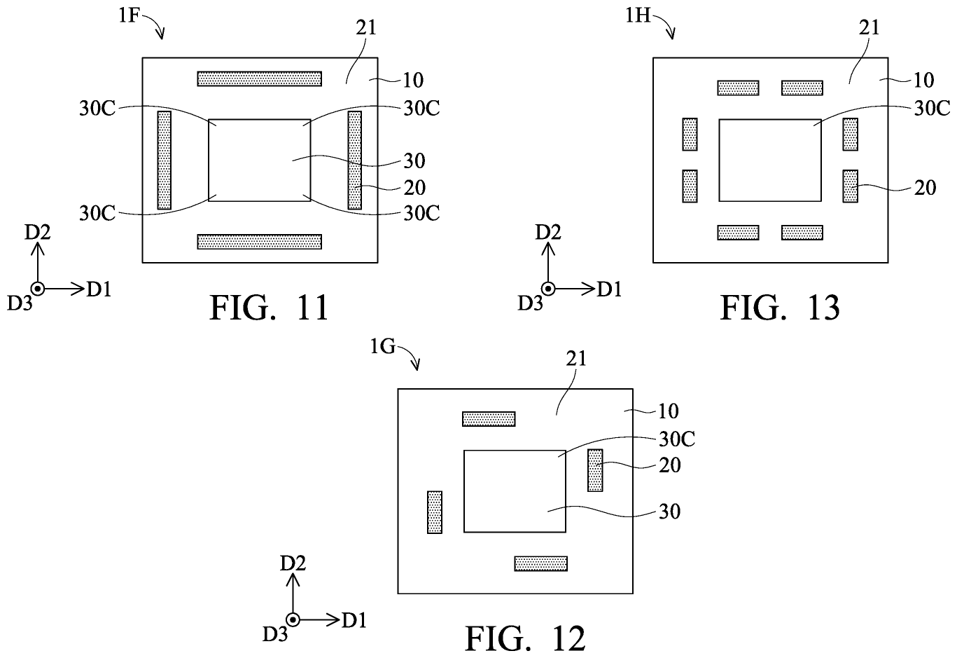

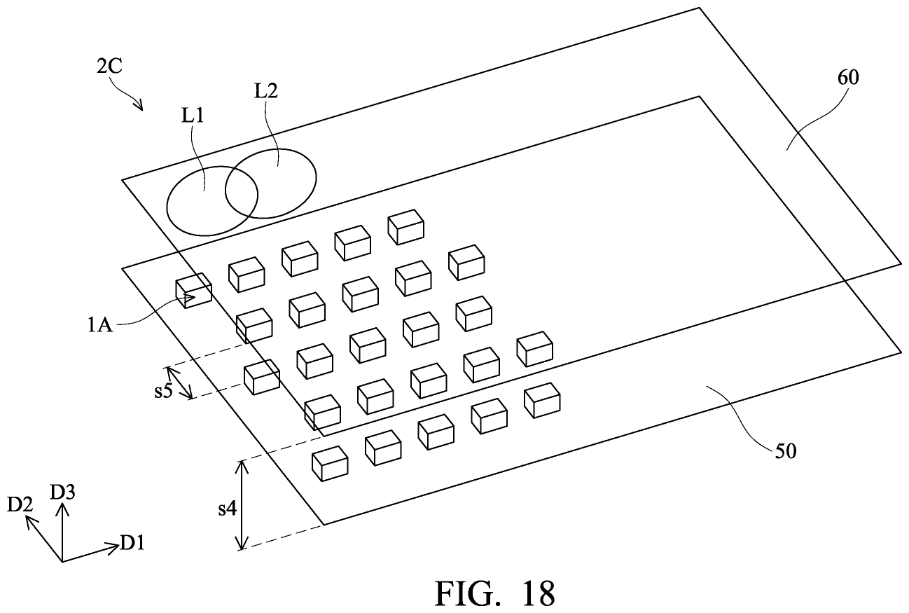

Referring to FIGS. 11 to 15, they respectively show schematic top views of packaged chips 1F to 1J according to some embodiments of the present disclosure. As shown in FIG. 11, in some embodiments, in the packaged chip 1F, the coupling portion 20 discontinuously surrounds the chip 30 to enhance the light-mixing capability of the portion of the chip 30 that is not surrounded by the coupling portion 20. In some embodiments, the coupling portion 20 may include a plurality of sub-coupling portions, and each of the plurality of sub-coupling portions is disposed on a different respective side of the chip 30. In the top view direction, the plurality of sub-coupling portions may discontinuously surround the chip 30. In the top view direction, the corner 30C of the chip 30 may correspond to the gap 21 between two adjacent sub-coupling portions, so as to improve the light-mixing capability of the corner 30C of the chip 30. The two adjacent sub-coupling portions may be any two adjacent sub-coupling portions among the plurality of sub-coupling portions. Furthermore, two adjacent sub-coupling portions may be respectively disposed on two adjacent sides of the chip 30. Therefore, the gap 21 between the two adjacent sub-coupling portions may correspond to the corner 30C of the chip 30, thereby improving the lighting requirement of the chip 30 on a diagonal direction (for example, on a direction having an included angle with the first direction D1 or the second direction D2, and the included angle may be 45 degrees or other suitable degrees). For example, when the chips 30 are arranged in an oblique symmetry manner as shown in FIG. 18, the packaged chip 1F may be used to improve the lighting characteristics of the chip 30 in the diagonal direction. For example, the possibility that the coupling portion 20 blocks the traveling path of light emitted from the chip 30 on the diagonal direction may be reduced.

As shown in FIG. 12, in the packaged chip 1G, the coupling portion 20 may include a plurality of sub-coupling portions, and each of the plurality of sub-coupling portions surrounds the chip 30 in an asymmetric manner, thereby increasing the impedance of the interface between the base material 10 and the packaging layer 40. In some embodiments, the corner 30C of the chip 30 may correspond to the gap 21 between two adjacent sub-coupling portions.

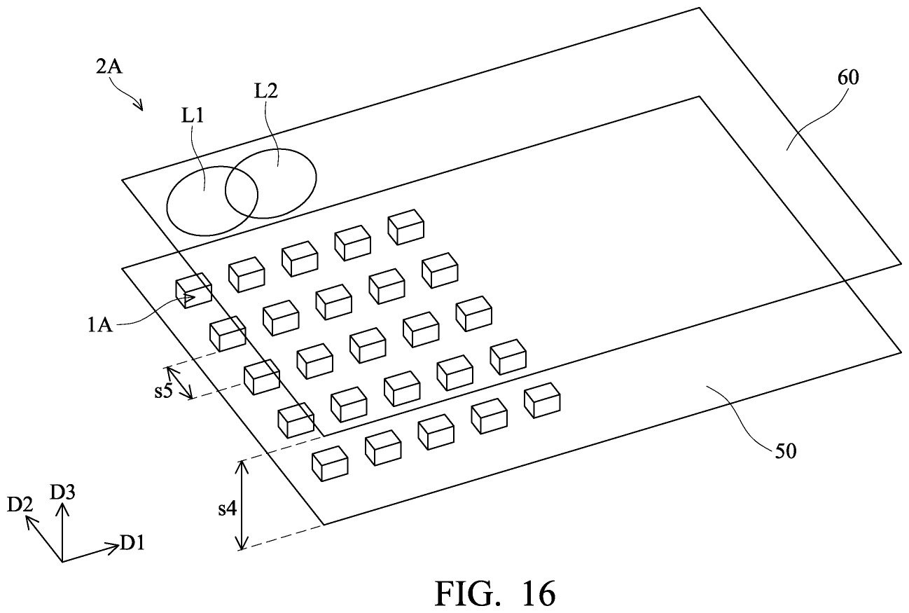

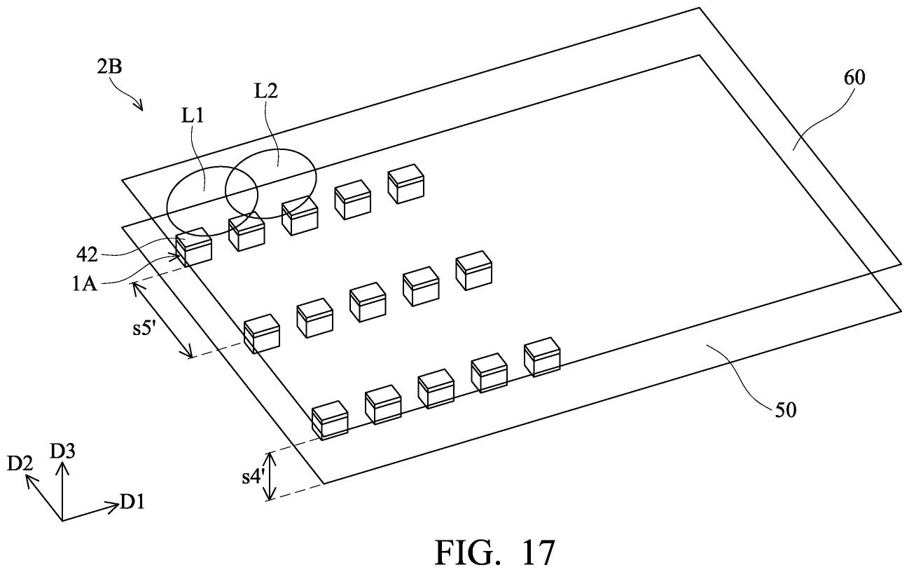

As shown in FIG. 13, in some embodiments, in the packaged chip 1H, the coupling portion 20 may include a plurality of sub-coupling portions, and at least some of the plurality of sub-coupling portions are disposed on one side of the chip 30, and at least some others of the plurality of sub-coupling portions are disposed on the other side of the chip 30. In some embodiments, two adjacent sub-coupling portions may be disposed on two adjacent sides of the chip 30 respectively. Therefore, the gap 21 between the two adjacent sub-coupling portions may correspond to the corner 30C of the chip 30, to improve the light-mixing capabilities of the chip 30 in the horizontal and vertical directions. For example, when the chips 30 are arranged in a matrix as shown in FIG. 16 or FIG. 17, the packaged chip 1G or the packaged chip 1H may be used to improve the lighting characteristics of the chip 30 in the horizontal and vertical directions.

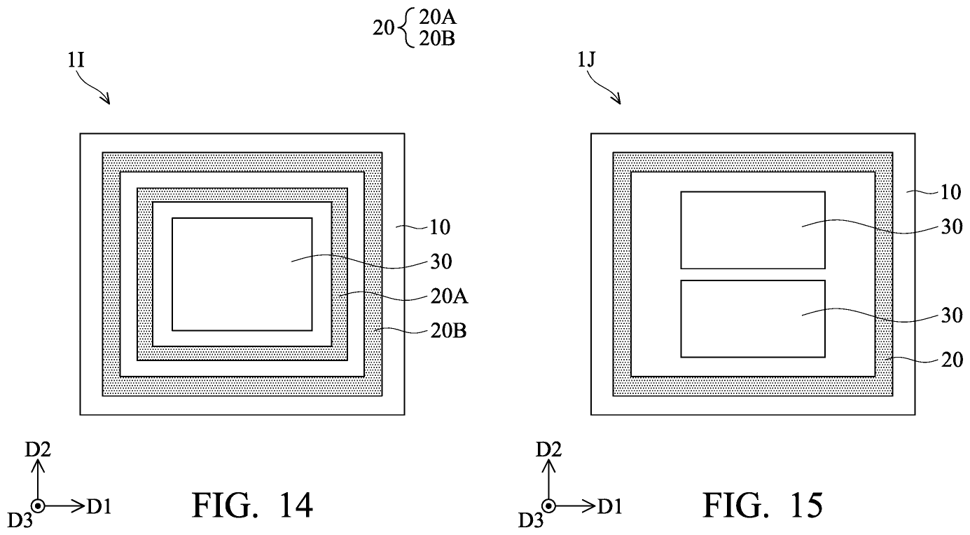

As shown in FIG. 14, in some embodiments, in the packaged chip 1I, the coupling portion 20 may include a first sub-coupling portion 20A and a second sub-coupling portion 20B. In some embodiments, the first sub-coupling portion 20A surrounds the chip 30 and the second sub-coupling portion 20B surrounds the first sub-coupling portion 20A. In some embodiments, the first sub-coupling portion 20A and the second sub-coupling portion 20B may be recesses, protrusions, or a combination thereof. In this embodiment, since the second sub-coupling portion 20B may be further away from the chip 30 than the first sub-coupling portion 20A, it is possible to avoid the coupling portion 20 from blocking the traveling path of the light emitted by the chip 30.

As shown in FIG. 15, in some embodiments, in the packaged chip 1J, the coupling portion 20 may surround at least two chips 30. For example, the coupling portion 20 may surround 2, 3, 4, or other numbers of chips 30.

In some embodiments, one or more of the packaged chips 1A to 1J may be used in a backlight module. In some embodiments, one or more of the packaged chips 1A to 1J may be arbitrarily combined and used in the same backlight module, or different packaged chips 1A to 1J may be selected to be used in different backlight modules according to the requirements.

Referring to FIG. 16, it shows a schematic diagram of a backlight module 2A according to some embodiments of the present disclosure. As shown in FIG. 16, the backlight module 2A may include a substrate 50 and a plurality of packaged chips 1A disposed on the substrate 50. In some embodiments, one or more packaged chips in the plurality packaged chips 1A may be replaced by one or more of the packaged chips 1B to 1J, or the plurality of packaged chips 1A may be replaced by a plurality of packaged chips 1B, 1C, 1D, 1E, 1F, 1G, 1H, or 1J. For ease of explanation, FIG. 16 shows that the backlight module 2A may include a packaged chip 1A, but the present disclosure is not limited thereto.

In some embodiments, the substrate 50 may include a foldable substrate, a flexible substrate, a rigid substrate, or a combination thereof, but the present disclosure is not limited thereto. In some embodiments, the substrate 50 may include glass, quartz, sapphire, ceramic, polyimide (PI), polycarbonate (PC), polyethylene terephthalate (PET), polypropylene (PP), other suitable materials, or a combination thereof, but the present disclosure is not limited thereto. In some embodiments, the substrate 50 may include a light-transmissive substrate, a semi-transparent substrate, or an opaque substrate. In some embodiments, the substrate 50 may include a thin film transistor (TFT) substrate to drive components disposed on the substrate 50.

The backlight module 2A may further include an optical film 60 disposed on the substrate 50 and the plurality of packaged chips 1A. In a normal direction of the substrate 50, the substrate 50 may at least partially overlap with the optical film 60. In some embodiments, the optical film 60 may be a single-layer or multi-layer structure. For example, the optical film 60 may include a diffusion layer, a brightness enhancement film (BEF), a dual brightness enhancement film (DBEF), the like, or a combination thereof, but the present disclosure is not limited thereto. In some embodiments, in the normal direction of the substrate 50, the substrate 50 and the optical film 60 may have a fourth distance s4 therebetween, and in the second direction D2 or the first direction D1, there may be a fifth distance s5 between adjacent packaged chips 1A of the plurality of packaged chips 1A. In some embodiments, the areas where the light emitted by the packaged chip 1A irradiates on the optical film 60 may be marked as areas L1 and L2 to show the lighting range of the packaged chip 1A.

Referring to FIG. 17, it shows a schematic diagram of a backlight module 2B according to some embodiments of the present disclosure. For ease of illustration, FIG. 17 shows that the backlight module 2B may include a packaged chip 1A, but the present disclosure is not limited thereto. In some embodiments, the backlight module 2B may further include a plurality of reflective layers 42, and each of the plurality of reflective layers 42 is disposed on the respective packaged chip 1A. In some embodiments, the reflectivity of the material of the reflective layer 42 may be greater than or equal to 90%. For example, the reflectivity of the material of the reflective layer 42 may be 90%, 95%, 97%, 99%, or any value or range of values between the abovementioned values, but the present disclosure is not limited thereto. In some embodiments, the reflective layer 42 may include white reflective material. In this embodiment, since the reflective layer 42 is disposed on the packaged chip 1A, the light-emitting angle or light-mixing capability of the chip 30 in the packaged chip 1A may be improved, thereby reducing the component density of the packaged chips 1A on the substrate 50 or reducing the overall thickness of the backlight module 2B. For example, the fourth distance s4 between the substrate 50 and the optical film 60 shown in FIG. 16 may be greater than the fourth distance s4′ between the substrate 50 and the optical film 60 shown in FIG. 17. For example, the fifth distance s5 between adjacent packaged chips 1A in the plurality of packaged chips 1A shown in FIG. 16 may be smaller than the fifth distance s5′ between adjacent packaged chips 1A in the plurality of packaged chips 1A shown in FIG. 17. For example, the areas L1 and L2 irradiated on the optical film 60 by the light emitted from the packaged chip 1A shown in FIG. 16 are similar to the areas L1 and L2 irradiated on the optical film 60 by the light emitted from the packaged chip 1A shown in FIG. 17.

Referring to FIG. 18, it shows a schematic diagram of a backlight module 2C according to some embodiments of the present disclosure. For ease of explanation, FIG. 18 shows that the backlight module 2C may include a packaged chip 1A, but the present disclosure is not limited thereto. As shown in FIG. 18, a plurality of packaged chips 1A are arranged in an obliquely symmetrical manner, so that the packaged chip 1F may be used instead of the packaged chip 1A to improve the lighting characteristics of the chip 30 in the diagonal direction.

In summary, according to some embodiments of the present disclosure, a packaged chip is provided that may increase the contact area between the base material and the packaging layer by disposing the coupling portion on the base material. Accordingly, the bonding strength between the base material and the packaging layer may be increased, the lighting efficiency, the lighting amount, and/or the light-mixing capability of the chip may be improved, and/or the reliability of the packaged chip may be improved.

The features among the various embodiments of the present disclosure may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the above-mentioned process, machine, manufacturing, material composition, device, method, and steps. The protection scope of the present disclosure shall be determined by the scope of the claims. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A packaged chip, comprising:
a base material comprising a first electrode;
a chip disposed on the base material and electrically connected with the first electrode; and
a packaging layer disposed on the base material and surrounding the chip,
wherein the base material comprises a surface, a first distance is between a top surface of the chip and the surface of the base material, the surface of the base material comprises a coupling portion, and in a cross-sectional direction, a height or a depth of the coupling portion is less than the first distance.

2. The packaged chip as claimed in claim 1, wherein the coupling portion is a protrusion, a recess, or a combination thereof.

3. The packaged chip as claimed in claim 1, wherein the chip comprises a second electrode, and wherein the second electrode overlaps the first electrode and is electrically connected to the first electrode.

4. The packaged chip as claimed in claim 1, wherein the coupling portion is disposed on an edge of the base material.

5. The packaged chip as claimed in claim 1, wherein in a top view direction, the coupling portion surrounds the chip.

6. The packaged chip as claimed in claim 1, wherein the base material further comprises an island portion, the coupling portion surrounds the island portion in the cross-sectional direction, and the chip is disposed on the island portion.

7. The packaged chip as claimed in claim 1, further comprising:
an air gap located between the coupling portion and the packaging layer.

8. The packaged chip as claimed in claim 1, wherein in a top view direction, the chip is spaced a second distance from an edge of the base material, the coupling portion is spaced a third distance from the edge of the base material, and the third distance is less than or equal to half of the second distance.

9. The packaged chip as claimed in claim 1, wherein in the cross-sectional direction, the height or the depth of the coupling portion is less than half of the first distance.

10. The packaged chip as claimed in claim 1, wherein in a top view direction, the coupling portion comprises a plurality of sub-coupling portions, and the plurality of sub-coupling portions discontinuously surrounds the chip, wherein a corner of the chip corresponds to a gap between two adjacent sub-coupling portions of the plurality of sub-coupling portions.

11. The packaged chip as claimed in claim 10, wherein the two adjacent sub-coupling portions are respectively disposed on two adjacent sides of the chip.

12. The packaged chip as claimed in claim 1, wherein the coupling portion is a protrusion, and the coupling portion has an arc top profile.

13. The packaged chip as claimed in claim 1, wherein the coupling portion is a recess, and the coupling portion has a tip bottom profile.

14. The packaged chip as claimed in claim 1, wherein the coupling portion comprises:
a first sub-coupling portion surrounding the chip; and
a second sub-coupling portion surrounding the first sub-coupling portion.

15. The packaged chip as claimed in claim 1, wherein the packaging layer comprises:
a packaging matrix; and
dispersed particles dispersed in the packaging matrix.

16. The packaged chip as claimed in claim 1, further comprising:
a bonding element disposed between the first electrode and the second electrode and electrically connected to the first electrode and the second electrode.

17. The packaged chip as claimed in claim 1, wherein the coupling portion surrounds at least two chips.

18. A backlight module, comprising:
a substrate; and
a plurality of packaged chips disposed on the substrate, wherein at least one of the plurality of packaged chips comprises:
a base material comprising a first electrode;
a chip disposed on the base material and electrically connected with the first electrode; and
a packaging layer disposed on the base material and surrounding the chip,
wherein the base material comprises a surface, a first distance is between a top surface of the chip and the surface of the base material, the surface of the base material comprises a coupling portion, and in a cross-sectional direction, a height or a depth of the coupling portion is less than the first distance.

19. The backlight module as claimed in claim 18, further comprising:
an optical film disposed on the plurality of packaged chips.

20. The backlight module as claimed in claim 18, further comprising:
a plurality of reflective layers, wherein each of the plurality of reflective layers is disposed on a respective packaged chip.
